(19) United States
(12) Patent Application Publication
(10) Pub. No.: US 2019/0155091 A1
(43) Pub. Date: May 23, 2019

(54) TFT ARRAY SUBSTRATE, MANUFACTURING METHOD AND LIQUID CRYSTAL DISPLAY PANEL

(71) Applicant: SHENZHEN CHINA STAR OPTOELECTRONICS SEMICONDUCTOR DISPLAY TECHNOLOGY CO., LTD., Shenzhen ,Guangdong (CN)

(72) Inventors: Chung-Jen CHEN, Shenzhen, Guangdong (CN); Yan-Ze LI, Shenzhen, Guangdong (CN); Chilin WU, Shenzhen, Guangdong (CN); Zhikun WU, Shenzhen, Guangdong (CN); Chun-An HSU, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen ,Guangdong (CN)

(21) Appl. No.: 15/748,318

(22) PCT Filed: Nov. 30, 2017
(86) PCT No.: PCT/CN2017/113732

§ 371 Date: Jan. 29, 2018

(30) Foreign Application Priority Data
Nov. 22, 2017 (CN) 201711175833.1

(51) Int. Cl. G02F 1/1335; H01L 23/31; G02F 1/1337; H01L 27/12

(52) U.S. Cl. CPC G02F 1/133514; H01L 23/3171; G02F 1/133512; G02F 2201/121; H01L 27/127; H01L 27/1218; G02F 2201/123; G02F 1/1337

(57) ABSTRACT

The present disclosure discloses a TFT array substrate, wherein the TFT array substrate is arranged with at least a base substrate, a thin film transistor layer, and a passivation layer and a pixel electrode layer on the thin film transistor layer; at least a via hole is formed on the passivation layer, supporters are arranged in the via hole, and the supporters have a same horizontal surface for supporting a lower surface of a CF substrate assembled with the TFT array substrate. The disclosure also discloses a corresponding manufacturing method and a liquid crystal display panel. The embodiment of the present disclosure can reduce the height difference of the via holes in the surface of the TFT array substrate, improve the thickness uniformity and flatness of the alignment film, so as to improve the display effect of the liquid crystal display panel.

### RELATED APPLICATIONS

The present application is a National Phase of International Application Number PCT/CN2017/113732, filed Nov. 30, 2017, and claims the priority of China Application CN 201711175833.1, filed Nov. 22, 2017.

### FIELD OF THE DISCLOSURE

The present disclosure relates to a display technology field, and more particularly to a TFT array substrate, a manufacturing method and a liquid crystal display panel.

### BACKGROUND OF THE DISCLOSURE

Liquid crystal displays (LCDs) have great market competitive advantages due to their mature technology and low cost, which can realize the advantages of high pixel density (Pixels Per Inch, PPI) and narrow bezel.

In the existing TFT-LCD process, the alignment film PI (Polyimide) process mainly uses PI liquid coating on the side of the TFT array substrate so that the liquid crystal molecules can be aligned in a specific direction. For example, the coating of the PI solution can be performed by a coating method such as drop and slit coating.

As shown in FIG. 1, a schematic diagram of a TFT array substrate of a conventional liquid crystal display device is shown. It can be seen that, the PI film 18′ is arranged on the passivation layer 16′. Due to the provision of the via 14′ on the passivation layer 16′, the surface has a large design height difference. However, because of these differences in height, there is a problem that uneven coating occurs when a PI film is formed by coating the PI solution. As in the via 14′, the thickness of the PI film is different from the thickness elsewhere, and is not flat enough. This in turn can cause the TFT-LCD display panel lighting picture appears uneven situation.

### SUMMARY OF THE DISCLOSURE

The technical problem to be solved by the present disclosure is to provide a TFT array substrate, a manufacturing method and a liquid crystal display panel, which can reduce the height difference of the via holes on the surface of the TFT array substrate, improve the thickness uniformity of the alignment film and improve the flatness, so as to improve the display effect of the liquid crystal display panel.

In order to solve the above technical problem, one aspect of an embodiment of the present disclosure provides a TFT array substrate, wherein the TFT array substrate is arranged with at least one base substrate, a thin film transistor layer, and a passivation layer and a pixel electrode layer on the thin film transistor layer; at least one via hole is formed on the passivation layer, supporters are arranged in the via hole, and the supporters have a same horizontal surface for supporting a lower surface of a CF substrate assembled with the TFT array substrate.

Wherein the TFT array substrate includes:

the base substrate;

the thin film transistor layer, a plurality of thin film transistor units formed on the thin film transistor layer, each thin film transistor unit including a gate, a gate insulating layer, an active layer, a source and a drain;

the passivation layer arranged on the thin film transistor layer and having at least one via hole, wherein a via hole exposes the source of the thin film transistor unit;

a pixel electrode arranged on the passivation layer and extending toward the via hole so as to be electrically connected to the source; and

an alignment layer covering the passivation layer and the pixel electrode.

Wherein the at least one via hole includes a first via hole arranged on a channel of the thin film transistor and a second via hole arranged on the source, in the second via hole, the pixel electrode layer is electrically connected to the source.

Wherein the supporter is columnar and made of the same material as the passivation layer.

Wherein a thickness of the pixel electrode is less than 300 A, and a thickness of the passivation layer 106 is between 1000 A and 2000 A.

Correspondingly, the present disclosure also provides a liquid crystal display panel including a TFT array substrate, a CF substrate, and a liquid crystal layer arranged between the TFT array substrate and the CF substrate, wherein:

the TFT array substrate is arranged with at least one base substrate, a thin film transistor layer, and a passivation layer and a pixel electrode layer on the thin film transistor layer; at least one via hole is formed on the passivation layer, a supporter is arranged in the via hole, and the supporters have a same horizontal surface for supporting a lower surface of the CF substrate.

Wherein the TFT array substrate includes:

the base substrate;

the thin film transistor layer, a plurality of thin film transistor units formed on the thin film transistor layer, each thin film transistor unit including a gate, a gate insulating layer, an active layer, a source and a drain;

the passivation layer arranged on the thin film transistor layer and having at least one via hole, wherein a via hole exposes the source of the thin film transistor unit;

a pixel electrode arranged on the passivation layer and extending toward the via hole so as to be electrically connected to the source; and

an alignment layer covering the passivation layer and the pixel electrode.

Wherein the at least one via hole includes a first via hole arranged on a channel of the thin film transistor and a second via hole arranged on the source, in the second via hole, the pixel electrode layer is electrically connected to the source.

Wherein the CF substrate includes:

a base substrate;

a black matrix layer arranged on a lower side of the base substrate of the CF substrate;

a color filter layer arranged on a lower side of the black matrix layer;

a common electrode layer arranged on a lower side of the color filter layer; and

a protective layer arranged on a lower side of the common electrode layer.

Wherein the supporter is columnar and made of the same material as the passivation layer.

Wherein a thickness of the pixel electrode is less than 300 A, and a thickness of the passivation layer 106 is between 1000 A and 2000 A.

Correspondingly, the present disclosure also provides a manufacturing method of a TFT array substrate, including the following steps:

forming a thin film transistor layer on a base substrate of a TFT array substrate, forming a plurality of thin film transistor units on the thin film transistor layer, each thin film transistor unit including a gate, a gate insulating layer, an active layer, a source and a drain;

forming a passivation layer arranged on the thin film transistor layer and forming at least one via hole on the passivation layer, wherein a via hole exposes the source of the thin film transistor unit;

forming a pixel electrode on the passivation layer, extending the pixel electrode toward the via hole and electrically connecting to the source;

forming supporters in the at least one via hole, wherein upper ends of the supporters have a same horizontal surface for supporting a lower surface of a CF substrate in a pair with the TFT array substrate; and

forming an alignment layer on the passivation layer and the pixel electrode.

Wherein the step of forming at least one via hole on the passivation layer specifically includes:

forming a first via hole over the channel of the thin film transistor on the passivation layer, forming a second via hole over the source, and electrically connecting the pixel electrode layer to the source in the second via hole.

The implementation of the embodiments of the present disclosure has the following beneficial effects:

In the TFT array substrate, the manufacturing method and the liquid crystal display panel provided by the present disclosure, the supporter is arranged in the via hole of the TFT array substrate, and then the alignment layer is formed. Since the lower portion of the supporter can occupy the space of the via hole, the height difference of the via hole on the surface of the TFT array substrate can be reduced, the thickness uniformity and the flatness of the alignment film can be improved. Thereby reducing the occurrence of non-uniform lighting of the TFT-LCD liquid crystal panel, so as to improve the display effect of the liquid crystal display panel.

### BRIEF DESCRIPTION OF THE DRAWINGS

To describe the technical solutions in the embodiments of the present disclosure or in the prior art more clearly, the following briefly introduces the accompanying drawings required for describing the embodiments or the prior art. Apparently, the accompanying drawings in the following description show merely some embodiments of the present disclosure, and persons of ordinary skill in the art may still derive other drawings from these accompanying drawings without creative efforts.

FIG. 1 is a schematic diagram of a TFT array substrate of a prior art liquid crystal display device;

FIG. 2 is a schematic structural diagram of an embodiment of a liquid crystal display panel provided by the present disclosure;

FIG. 3 is a schematic structural diagram of another embodiment of a liquid crystal display panel provided by the present disclosure;

FIG. 4 is a main flow diagram of an embodiment of a manufacturing method of a liquid crystal display panel provided by the present disclosure.

### DETAILED DESCRIPTION OF PREFERRED EMBODIMENTS

The technical solutions in the embodiments of the present disclosure will be described clearly and completely below with reference to the accompanying drawings in the embodiments of the present disclosure. Apparently, the described embodiments are merely some but not all embodiments of the present disclosure. All other embodiments obtained by a person of ordinary skill in the art based on the embodiments of the present disclosure without creative efforts shall fall within the protection scope of the present disclosure.

Here, it should also be noted that, in order to avoid obscuring the present disclosure with unnecessary detail, only the structures and/or processing steps that are closely related to the solution according to the present disclosure are shown in the drawings, and other details that are of less concern to the present disclosure are omitted.

As shown in FIG. 2, FIG. 2 is a schematic structural diagram of an embodiment of a liquid crystal display panel provided by the present disclosure. In the present embodiment, the liquid crystal display device includes at least one liquid crystal cell, wherein the liquid crystal cell includes a TFT array substrate 10, a CF substrate 16 and a liquid crystal layer 13 between the TFT array substrate 10 and the CF substrate 16 arranged opposite to each other.

The TFT array substrate 10 is provided with at least a base substrate 100, a thin film transistor layer, and a passivation layer 106 and a pixel electrode layer 107 on the thin film transistor layer. At least one via hole 12, 14 is formed on the passivation layer. A supporter 15 is arranged in the via hole, and the supporters have a same horizontal surface for supporting a lower surface of the CF substrate 16. In an example, the supporter is columnar and made of the same material as the passivation layer 106. For example, the supporter may be a resin material.

Specifically, the TFT array substrate 10 includes:

the base substrate 100, which may be a glass substrate or a PI (polyimide) substrate;

a thin film transistor layer arranged on the base substrate 100, a plurality of thin film transistor units formed on the thin film transistor layer, wherein each thin film transistor layer unit includes a gate 101, a gate insulating layer 102, an active layer 103, a source 104 and a drain 105. The active layer 103 can be made of material such as amorphous silicon, IGZO or polysilicon. The gate 101, the source 104 and the drain 105 are all metal layers, and the gate insulating layer 102 can be made of a material such as SiNx or SiOx. It is understood that the above “on” refers to the side close to the liquid crystal layer 13;

a passivation layer 106 arranged on the thin film transistor layer and having at least one via hole, wherein one via hole exposes the source 104 of the thin film transistor unit; specifically, the at least one via hole includes a first via hole 12 arranged on the channel of the thin film transistor, and a second via hole 14 arranged on the source 104;

a pixel electrode 107 arranged on the passivation layer 106 and extending toward the second via hole 14. In the second via hole 14, the pixel electrode layer 107 is electrically connected to the source 104. The pixel electrode 107 may be a metal oxide film, such as ITO;

an alignment layer 108 covers the passivation layer 106 and the pixel electrode 107. In one example, the alignment layer 108 has a thickness of 10-100 μm.

Wherein the CF substrate 16 includes:

a base substrate 160, which may be a glass substrate or a PI (polyimide) substrate;

a black matrix layer 161 arranged on a lower side of the base substrate 160 of the CF substrate 16 faces the thin film transistor unit in the TFT array substrate 10. It can be understood that the “lower side” is close to the side of the liquid crystal layer 13;

a color filter layer 162 arranged on a lower side of the black matrix layer 161 and specifically includes a red filter, a blue filter, and a green filter;

a common electrode layer 163 is arranged under the color filter layer 162 and may be made of ITO (Indium Tin Oxide) material; and

a protective layer 164 arranged on a lower side of the common electrode layer 163.

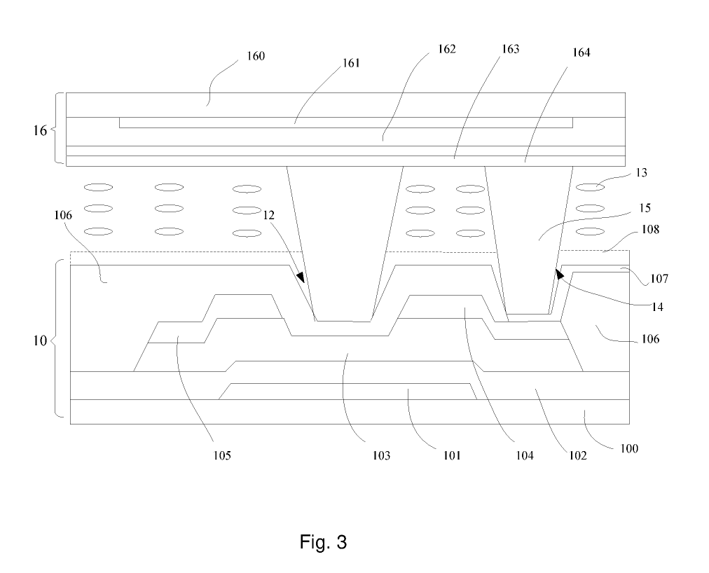

As shown in FIG. 3, a schematic structural diagram of another embodiment of a liquid crystal display panel according to the present disclosure is shown. In this embodiment, this is different from the structure in the embodiment shown in FIG. 2 in that the shape of the supporter 15 is changed, which is a column having an inverted trapezoid in longitudinal section, in this way, the lower end can fill the first via hole 12 and the second via hole better. Also, in other embodiments, the supporter 15 can also adopt an irregular shape.

For other structures, reference may be made to the foregoing description of FIG. 2, which is not described in detail here.

It can be understood that in some other embodiments, the thickness of the passivation layer 106 can be reduced so as to reduce the depth of the via hole and reduce the thickness of the pixel electrode 107 to reduce the design height difference. Likewise, the alignment layer 108 can be smoothed.

Specifically, in some examples, the thickness of the pixel electrode 107 can be controlled within 300 A; by reducing the thickness of the pixel electrode 107, surface uniformity can be improved.

In the meantime, in some embodiments, the thickness of the passivation layer 106 can be set to be between 1000 A and 2000 A. It can be understood that the thickness of the passivation layer needs to be determined at the same time considering the insulation requirements of the product.

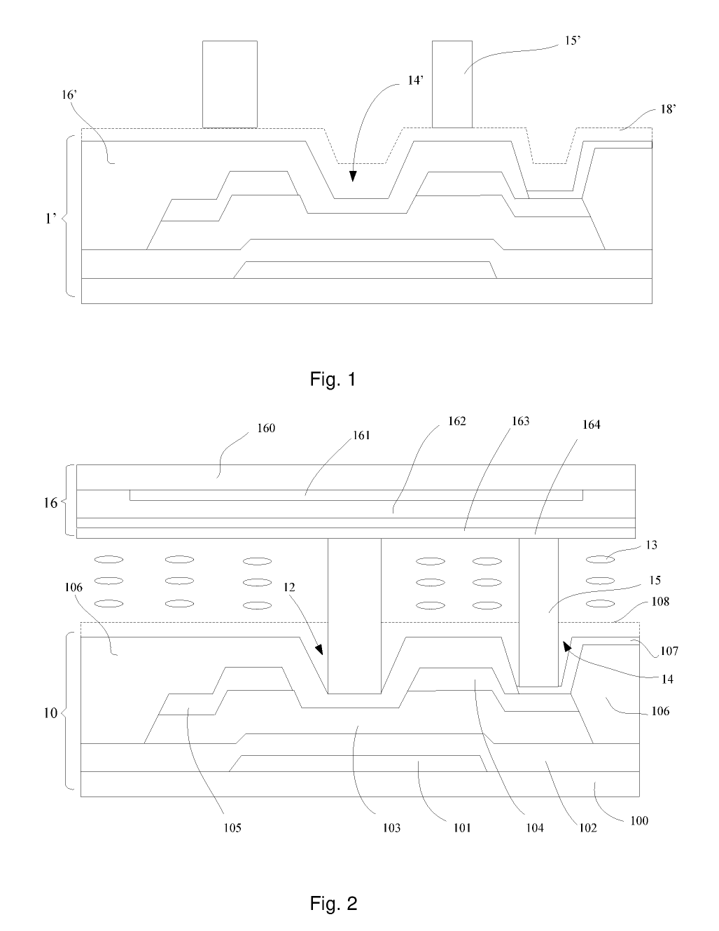

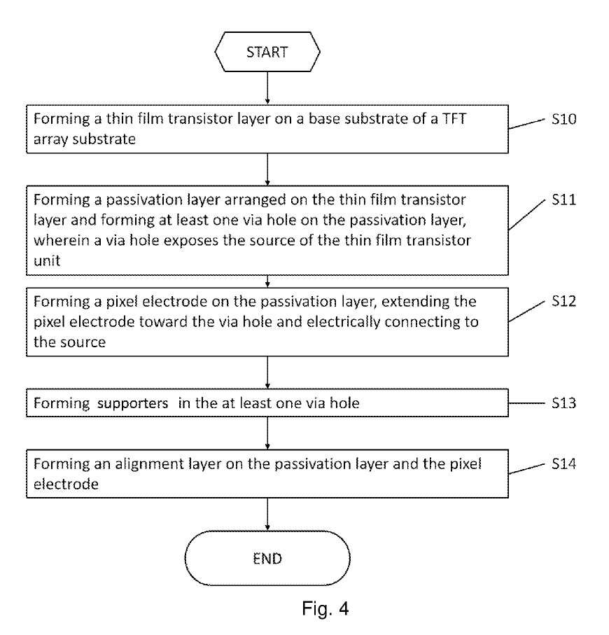

As shown in FIG. 4, it is shown that FIG. 4 is a main flow diagram of an embodiment of a manufacturing method of a liquid crystal display panel according to the present disclosure. The method is used to fabricate the liquid crystal display panel shown in FIG. 1. Specifically, in this embodiment, the method includes the following steps:

step S10, forming a thin film transistor layer on a base substrate of a TFT array substrate, and forming a plurality of thin film transistor units on the thin film transistor layer, wherein each thin film transistor layer unit includes a gate, a gate insulating layer, an active layer, a source and a drain respectively; it can be understood that the specific process of forming the thin film transistor layer can refer to the prior art and will not be described in detail herein;

step S11, forming a passivation layer arranged on the thin film transistor layer and forming at least a via hole on the passivation layer, wherein a via hole exposes the source of the thin film transistor unit; in an embodiment, forming a first via hole on the channel of the thin film transistor on the passivation layer, forming a second via hole on the source, and electrically connecting the pixel electrode layer to the source in the second via hole;

step S12, forming a pixel electrode on the passivation layer, extending the pixel electrode toward the via hole and electrically connecting to the source;

step S13, forming supporters in the at least one via hole, wherein upper ends of the supporters have a same horizontal surface for supporting a lower surface of a CF substrate in a pair with the TFT array substrate;

step S14, forming an alignment layer on the passivation layer and the pixel electrode.

It can be understood that in the embodiment of the present disclosure, the supporter is arranged in the via hole of the passivation layer first, at this time, the lower portion of the supporter may occupy the space of the via hole, so that the height difference of the via holes on the surface of the TFT array substrate can be reduced; then, the alignment layer is coated to improve the south uniformity and the flatness of the alignment thickness.

In the meantime, in some embodiments of the present disclosure, after forming the alignment layer, some supporters may still be arranged on the alignment layer to improve the supporting effect.

The implementation of the embodiments of the present disclosure has the following beneficial effects:

In the TFT array substrate, the manufacturing method and the liquid crystal display panel provided by the present disclosure, the supporter is arranged in the via hole of the TFT array substrate, and then the alignment layer is formed. Since the lower portion of the supporter can occupy the space of the via hole, the height difference of the via hole on the surface of the TFT array substrate can be reduced, the thickness uniformity and the flatness of the alignment film can be improved. Thereby reducing the occurrence of non-uniform lighting of the TFT-LCD liquid crystal panel, so as to improve the display effect of the liquid crystal display panel.

It should be noted that, in this article, relational terms, such as first and second, and the like, are only used to distinguish one entity or operation from another, without necessarily requiring or implying any actual relationship or order between such entities or operations. Moreover, the terms “comprising,” “including,” or any other variation thereof, are intended to cover a non-exclusive inclusion such that a process, method, article, or apparatus that includes a list of elements includes not only those elements, but also include other elements not expressly listed or also include elements inherent to the process, method, article, or device. Without further limitations, an element limited by the statement “including a . . . ” does not exclude the existence of additional identical elements in the process, method, article, or apparatus that includes the element.

The foregoing descriptions are merely specific implementation manners of the present application. It should be noted that, for those skilled in the art, several improvements and modifications can be made without departing from the principle of the present disclosure, and these improvements and modifications should also be considered as the protection scope of the present application.

What is claimed is:

1. A TFT array substrate, comprising:
at least one base substrate and a thin film transistor layer arranged on the TFT array substrate;
a passivation layer and a pixel electrode arranged on the thin film transistor layer, wherein a via hole is formed on the passivation layer, supporters are arranged in the via hole, and the supporters are at the same horizontal level for supporting a lower surface of a CF substrate assembled with the TFT array substrate.

2. The TFT array substrate according to claim 1, wherein the TFT array substrate comprises:
the base substrate;
the thin film transistor layer, a plurality of thin film transistor units formed on the thin film transistor layer, each thin film transistor unit comprising a gate, a gate insulating layer, an active layer, a source and a drain;
the passivation layer arranged on the thin film transistor layer and having at least one via hole, wherein a via hole exposes the source of the thin film transistor unit;
a pixel electrode arranged on the passivation layer and extending toward the via hole so as to be electrically connected to the source; and
an alignment layer covering the passivation layer and the pixel electrode.

3. The TFT array substrate according to claim 2, wherein the at least one via hole comprises a first via hole arranged on a channel of the thin film transistor and a second via hole arranged on the source, in the second via hole, the pixel electrode layer is electrically connected to the source.

4. The TFT array substrate according to claim 3, wherein the supporter is columnar and made of the same material as the passivation layer.

5. The array substrate according to claim 1, wherein a thickness of the pixel electrode is less than 300 A, and a thickness of the passivation layer 106 is between 1000 A and 2000 A.

6. The array substrate according to claim 2, wherein a thickness of the pixel electrode is less than 300 A, and a thickness of the passivation layer 106 is between 1000 A and 2000 A.

7. The array substrate according to claim 3, wherein a thickness of the pixel electrode is less than 300 A, and a thickness of the passivation layer 106 is between 1000 A and 2000 A.

8. The array substrate according to claim 4, wherein a thickness of the pixel electrode is less than 300 A, and a thickness of the passivation layer 106 is between 1000 A and 2000 A.

9. A liquid crystal display panel, comprising: a TFT array substrate, a CF substrate, and a liquid crystal layer arranged between the TFT array substrate and the CF substrate, wherein:
the TFT array substrate is arranged with at least one base substrate, a thin film transistor layer, and a passivation layer and a pixel electrode layer on the thin film transistor layer; at least one via hole is formed on the passivation layer, supporters are arranged in the via hole, and the supporters have a same horizontal surface for supporting a lower surface of the CF substrate.

10. The liquid crystal display panel according to claim 9, wherein the TFT array substrate comprises:
the base substrate;
the thin film transistor layer, a plurality of thin film transistor units formed on the thin film transistor layer, each thin film transistor unit comprising a gate, a gate insulating layer, an active layer, a source and a drain;
the passivation layer arranged on the thin film transistor layer and having at least one via hole, wherein a via hole exposes the source of the thin film transistor unit;
a pixel electrode arranged on the passivation layer and extending toward the via hole so as to be electrically connected to the source; and
an alignment layer covering the passivation layer and the pixel electrode.

11. The liquid crystal display panel according to claim 10, wherein the at least one via hole comprises a first via hole arranged on a channel of the thin film transistor and a second via hole arranged on the source, in the second via hole, the pixel electrode layer is electrically connected to the source.

12. The liquid crystal display panel according to claim 11, wherein the CF substrate comprises:
a base substrate;
a black matrix layer arranged on a lower side of the base substrate of the CF substrate;
a color filter layer arranged on a lower side of the black matrix layer;
a common electrode layer arranged on a lower side of the color filter layer; and
a protective layer arranged on a lower side of the common electrode layer.

13. The liquid crystal display panel according to claim 12, wherein the supporter is columnar and made of the same material as the passivation layer.

14. The liquid crystal display panel according to claim 13, wherein a thickness of the pixel electrode is less than 300 A, and a thickness of the passivation layer 106 is between 1000 A and 2000 A.

15. A manufacturing method of a TFT array substrate, comprising the steps of:
forming a thin film transistor layer on a base substrate of a TFT array substrate, forming a plurality of thin film transistor units on the thin film transistor layer, each thin film transistor unit comprising a gate, a gate insulating layer, an active layer, a source and a drain;
forming a passivation layer arranged on the thin film transistor layer and forming at least one via hole on the passivation layer, wherein a via hole exposes the source of the thin film transistor unit;
forming a pixel electrode on the passivation layer, extending the pixel electrode toward the via hole and electrically connecting to the source;
forming supporters in the at least one via hole, wherein upper ends of the supporters have a same horizontal surface for supporting a lower surface of a CF substrate in a pair with the TFT array substrate; and
forming an alignment layer on the passivation layer and the pixel electrode.

16. The method according to claim 15, wherein the step of forming at least one via hole on the passivation layer specifically comprises:
forming a first via hole over the channel of the thin film transistor on the passivation layer, forming a second via hole over the source, and electrically connecting the pixel electrode layer to the source in the second via hole.
